(19) United States
(12) Patent Application Publication
(10) Pub. No.: US 2010/0307914 A1
(43) Pub. Date: Dec. 9, 2010

(54) Cu-Ga ALLOY, SPUTTERING TARGET, Cu-Ga ALLOY PRODUCTION METHOD, AND SPUTTERING TARGET PRODUCTION METHOD

(75) Inventors: Yuichi HIRAMOTO, Tsuchiura (JP); Tatsuya Tonogi, Tsuchiura (JP)

Correspondence Address: FOLEY AND LARDNER LLP;SUITE 500, 3000 K STREET NW, WASHINGTON, DC, 20007, US

(73) Assignee: HITACHI CABLE, LTD.

(21) Appl. No.: 12/777,574

(22) Filed: May 11, 2010

(30) Foreign Application Priority Data
Jun. 4, 2009 (JP) 2009-134675

(51) Int. Cl. C23C 14/34; C22C 28/00; C22C 9/00; B22F 9/06; B22F 3/00

(52) U.S. Cl. 204/298.13; 420/555; 420/489; 75/331; 419/61

(57) ABSTRACT

A Cu—Ga alloy includes a plurality of phases, and not less than 40 wt % and not more than 60 wt % of gallium (Ga) and a balance consisting of copper and an inevitable impurity. The plurality of phases include a segregation phase including not less than 80 wt % of gallium (Ga), and a rate of a volume of the segregation phase to a total volume of the Cu—Ga alloy is not more than 1%. The plurality of phases include particles including not less than 40 wt % and not more than 60 wt % of gallium (Ga), the particles include a diameter of not less than 0.1 μm and not more than 30 μm, and a rate of a volume of the particles to the total volume of the Cu—Ga alloy is not less than 90%.

The present application is based on Japanese patent application No. 2009-134675 filed on Jun. 4, 2009, the entire contents of which are incorporated herein by reference.

### BACKGROUND OF THE INVENTION

1. Field of the Invention

This invention relates to a Cu—Ga alloy, a sputtering target, a Cu—Ga alloy production method, and a sputtering target production method. In particular, this invention relates to a Cu—Ga alloy, a sputtering target, a Cu—Ga alloy production method, and a sputtering target production method for applying to solar cells.

2. Description of the Related Art

A Cu—Ga binary alloy sputtering target is known that comprises a component part of 30 mass % to 60 mass % Ga and a balance consisting of Cu, and a two-phase coexistence system that a high Ga containing Cu—Ga binary alloy particle including more than 30 mass % Ga and a balance consisting of Cu is encompassed by a grain boundary phase comprising a low Ga containing Cu—Ga binary alloy including 15 mass % or less Ga (See e.g., JP-A-2008-138232).

The Cu—Ga binary alloy sputtering target disclosed in JP-A-2008-138232 thus composed can be produced in good yield ratio, wherein the sputtering target is used in forming a light absorption layer comprising a Cu—In—Ga—Se quaternary alloy film for solar cells.

Here, the Cu—Ga binary alloy sputtering target disclosed in JP-A-2008-138232 is produced by sintering a raw material powder. Therefore, it is difficult to densify the sputtering target system produced and a problem such as abnormal electrical discharge may occur in sputtering. Further, when a Cu—Ga binary alloy including 45 wt % to 60 wt % Ga is melt and sintered, a segregation phase including 70 wt % or more Ga may occur. If the sputtering target including the segregation phase is used, the segregation phase may be melt by heat in the sputtering.

### SUMMARY OF THE INVENTION

It is an object of the invention to provide a Cu—Ga alloy, a sputtering target, a Cu—Ga alloy production method, and a sputtering target production method for exhibiting a densified system and reducing the segregation phase.

(1) According to one embodiment of the invention, a Cu—Ga alloy comprises:

a plurality of phases; and

not less than 40 wt % and not more than 60 wt % of gallium (Ga) and a balance consisting of copper and an inevitable impurity,

wherein the plurality of phases comprise a segregation phase including not less than 80 wt % of gallium (Ga), and

a rate of a volume of the segregation phase to a total volume of the Cu—Ga alloy is not more than 1%.

In the above embodiment (1), the following modifications and changes can be made.

(i) The plurality of phases comprise particles including not less than 40 wt % and not more than 60 wt % of gallium (Ga), the particles comprise a diameter of not less than 0.1 μm and not more than 30 μm, and a rate of a volume of the particles to the total volume of the Cu—Ga alloy is not less than 90%.

(2) According to another embodiment of the invention, a Cu—Ga alloy comprises:

a plurality of phases; and

not less than 40 wt % and not more than 60 wt % of gallium (Ga) and a balance consisting of copper and an inevitable impurity,

wherein the plurality of phases comprise a γ3 phase and an ε phase comprising an alloy of copper and gallium (Ga), and

a rate of a total volume of the γ3 phase and the ε phase to a total volume of the Cu—Ga alloy is not less than 99%.

In the above embodiment (2), the following modifications and changes can be made.

(ii) The γ3 phase comprises particles with a diameter of not less than 0.1 μm and not more than 30 μm, and a rate of a volume of the γ3 phase to the total volume of the Cu—Ga alloy is not less than 90%.

(3) According to another embodiment of the invention, a sputtering target comprises the Cu—Ga alloy according to the embodiment (1) or (2).
(4) According to another embodiment of the invention, a method of making a Cu—Ga alloy comprises:

melting by heating a mixture that comprises not less than 40 wt % and not more than 60 wt % of gallium (Ga) and a balance consisting of copper and an inevitable impurity; and

cooling the molten mixture to 254° C. to solidify particles comprising not less than 40 wt % and not more than 60 wt % of gallium (Ga), and a diameter of not less than 0.1 μm and not more than 30 μm, such that a rate of a volume of the particles to a total volume of the Cu—Ga alloy is not less than 90%.

In the above embodiment (4), the following modifications and changes can be made.

(iii) The method further comprises:

after the cooling, conducting a thermal treatment at a temperature of not less than 200° C. and not more than 254° C. and for not less than 8 hours.

(iv) The cooling comprises cooling the molten mixture to 254° C. at a cooling speed of 20° C./sec.

(v) The melting comprises melting the mixture put in a water-cooling mold or a crucible and the cooling comprises cooling directly the water-cooling mold or the crucible.

(5) According to another embodiment of the invention, a method of making a sputtering target comprises:

forming the Cu—Ga alloy made by the method according to the embodiment (4) into the sputtering target with a predetermined shape.

Points of the Invention

According to one embodiment of the invention, the amount of segregation phase existing in the alloy finally produced can be reduced by decreasing the diameter of γ3 phase particles in the period after the start of cooling the molten alloy and until the molten alloy reaches a temperature of 254° C. where the ε phase starts to deposit in order to decrease the segregation phase in the Cu—Ga alloy. In other words, the gap between the γ3 phase crystal particles can be narrowed by decreasing the diameter of the γ3 phase particles such that the Ga system existing in the gap can be finely structured. Due to this fine structure, the reaction into ε phase can be enhanced to reduce the remaining segregation phase.

### BRIEF DESCRIPTION OF THE DRAWINGS

The preferred embodiments according to the invention will be explained below referring to the drawings, wherein:

FIG. 1 is a flow chart showing a production flow of a Cu—Ga alloy in an embodiment of the invention; and

FIG. 2 is a graph showing the relationship between heat treatment time and segregation phase area ratio.

### DETAILED DESCRIPTION OF THE PREFERRED EMBODIMENTS

### Findings of the Inventors

Cu—Ga alloys in embodiment of the invention are based on findings of the inventors as below.

At first, when a molten alloy obtained by heating copper (Cu) including about 45 wt % to 60 wt % gallium (Ga) is cooled, the solidification of the molten alloy begins at 650° C. to 780° C. theoretically in phase diagram. Due to the solidification, copper alloy including 40 wt % to 45 wt % Ga, i.e., γ3 phase is deposited. The γ3 phase exists in the molten alloy as a crystal particle with a diameter of tens to hundreds μm (hereinafter the γ3 phase referred to as “primary crystal”).

Then, when temperature becomes below 254° C. by cooling continuously, a liquid phase with higher Ga concentration than the γ3 phase Ga concentration is deposited (i.e., the primary crystal and the liquid phase cause a peritectic reaction), infilling gaps among γ3 phase crystal particles theoretically in phase diagram. The deposition is ε phase including 68 wt % to 70 wt % Ga. Here, in reality, a liquid phase including 80 wt % or more Ga may remain unreacted into the Ga—Cu alloy. This phase is called segregation phase. Although the segregation phase is solidified below about 29° C., the segregation phase may be melt by heat generated in the sputtering when using a sputtering target formed of a Cu—Ga alloy including the segregation phase since the melting point is low due to the high concentration Ga.

The inventors have found that the segregation phase is formed by the following reason. For example, due to low temperature for cooling the molten alloy, the liquid phase existing among the primary crystal solid phases is low in atomic diffusion rate. Therefore, especially Ga in the liquid phase remains unreacted into the ε phase to cause the high Ga concentration liquid phase. The inventors have found the above reason.

In consideration of the above, the inventors have found that the amount of segregation phase existing in the alloy finally produced can be reduced by decreasing the diameter of γ3 phase particles in the period after the start of cooling the molten alloy and until the molten alloy reaches a temperature of 254° C. where the ε phase starts to deposit in order to decrease the segregation phase in the Cu—Ga alloy. In other words, the gap between the adjoining γ3 phase crystal particles can be narrowed by decreasing the diameter of the γ3 phase particles such that the Ga system existing in the gap can be finely structured. The inventors reach an idea that due to this fine structure, the reaction into ε phase can be enhanced to reduce the remaining segregation phase.

For example, the inventors have found that the rate of the volume of the segregation phase to the total volume of the Cu—Ga alloy finally produced can be reduced to 1% or less by controlling the diameter of γ3 phase particles deposited to be not more than 30 μm until the molten alloy is cooled to 254° C. Also, the inventors have found that it is effective that the cooling speed in cooling the molten alloy 254° C. is set to be more than that of the conventional method in order to control the diameter of the crystal particles to be not more than 30 μm until the molten alloy reaches a temperature of 254° C. where the ε phase starts to deposit. For example, the inventors have found that the diameter of the γ3 phase crystal particles can be controlled to be not more than 30 μm by setting the cooling speed to be not less than 20° C./sec.

Further, by retaining the molten alloy at a temperature less than 254° C. after the temperature of the molten alloy reaches 254° C. where ε phase starts to deposit, the atomic diffusion rate in liquid phase can be kept at a predetermined rate. The inventors have found that this can prevent the deposition of the segregation phase including high concentration Ga, and allow liquid phase existing among γ3 phases to be reacted into ε phase. For example, it is found by the inventors that, by retaining the molten alloy at a temperature not less than 220° C. and not more than 254° C. for 8 hours or more after the temperature of the molten alloy reaches 254° C., the rate of the volume of the segregation phase to the total volume of the Cu—Ga alloy finally produced can be reduced to 1% or less. The preferred embodiments according to the invention will be explained below.

### EMBODIMENTS

### Outline of Cu—Ga Alloys

The Cu—Ga alloys in the embodiment are, e.g., a Cu—Ga alloy used in forming a light absorption layer etc. of a thin-film solar cell of a compound semiconductor. For example, in a solar cell, which comprises a glass substrate of soda-lime glass etc., an electrode layer formed on the glass substrate, a light absorption layer formed on the electrode layer, a buffer layer formed on the light absorption layer, and a transparent electrode layer formed on the buffer layer, the Cu—Ga alloys of the embodiment can be used as a material for composing the light absorption layer. The electrode layer may be, e.g., molybdenum (Mo) electrode as a positive electrode and the light absorption layer may be, e.g., Cu—In—Ga—Se quaternary alloy layer. The buffer layer may be of ZnS, CdS etc., and the transparent electrode layer functions as a negative electrode.

For example, the Cu—Ga alloy of the embodiment is a Cu—Ga alloy including plural phases, and it comprises not less than 40 wt % and not more than 60 wt % of Ga, and a balance consisting of Cu and inevitable impurity. Further, the Cu—Ga alloy of the embodiment comprises a segregation phase including 80 wt % or more of Ga, and the rate of the volume of the segregation phase to the total volume of the Cu—Ga alloy is controlled to be 1% or less. Further, the Cu—Ga alloy comprises particles including not less than 40 wt % and not more than 60 wt % of Ga, and the particles have a diameter of not less than 0.1 μm and not more than 30 μm, and the rate of the volume of the particles to the total volume of the Cu—Ga alloy is preferably 90% or more.

In terms of the plural phases, the Cu—Ga alloy of the embodiment is defined as having γ3 and ε phase Cu—Ga alloys. The rate of the total volume of the γ3 and ε phases to the total volume of the Cu—Ga alloy is controlled to be 99% or more. The γ3 phase of the Cu—Ga alloy of the embodiment may comprise a Cu—Ga alloy including particles have a diameter of not less than 0.1 μm and not more than 30 μm. The rate of the volume of the γ3 phase to the total volume of the Cu—Ga alloy is preferably 90% or more.

The Cu—Ga alloy of the embodiment may be formed into a predetermined shape such as a disk or rectangle to provide a sputtering target formed of a Cu—Ga alloy in the embodiment.

Production Method of Cu—Ga Alloy

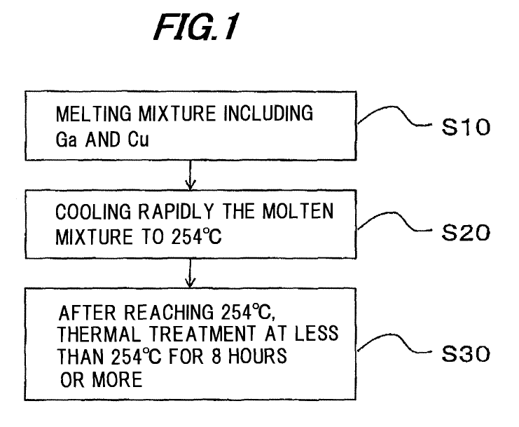

FIG. 1 is a flow chart showing an example of a production flow of the Cu—Ga alloy in the embodiment of the invention.

The Cu—Ga alloy in the embodiment can be produced by melting a raw material and then rapidly cooling and solidifying the molten raw material. For example, at first, a mixture including not less than 40 wt % and not more than 60 wt % of Ga and a balance consisting of Cu and inevitable impurity is heated and melted in a melting furnace (Melting step: step 10) (hereinafter “step *” being referred to as “S *”). For example, the mixture as a raw material is melted by heating at 780° C. or more. The melting step is performed such that the mixture is put in a water-cooling mold or crucible and the water-cooling mold or crucible is then heated to melt the mixture.

Then, the molten mixture is cooled to 254° C. (Cooling step: S20). For example, the molten mixture (e.g., a molten mixture in a state of being heated at about 650° C. to 780° C. after melting) is rapidly cooled to 254° C. The molten mixture in the water-cooling mold or crucible may be rapidly cooled to 254° C. by cooling directly the water-cooling mold or crucible at a cooling rate of 20° C./sec.

By the cooling step, solidified in the molten mixture are particles that include not less than 40 wt % and not more than 60 wt % of Ga, and have a diameter of not less than 0.1 μm and not more than 30 μm. Thereby, the Cu—Ga alloy can be formed such that the rate of the volume of the particles to the total volume of the Cu—Ga alloy is 90% or more.

Then, after temperature in the water-cooling mold or crucible reaches 254° C. at the cooling step, thermal treatment is provided for the water-cooling mold or crucible at temperature of not less than 200° C. and less than 254° C. for 8 hours to 120 hours (Thermal treatment step: S30). Thereby, ε phase of the Cu—Ga alloy is deposited among plural γ3 phases. Thus, by the thermal treatment step, the reaction into ε phase of liquid phase existing among γ3 phases can be enhanced to reduce the deposition of segregation phase.

By completing the above steps, the Cu—Ga alloy (including the γ3 phase and ε phase) of the embodiment can be produced that the rate of the volume of the segregation phase including not less than 70 wt % of Ga to the total volume of the Cu—Ga alloy is 1% or less.

The Cu—Ga alloy thus produced by completing the above steps may undergo a step (e.g., step for forming the Cu—Ga alloy into a predetermined shape) for making a sputtering target with a predetermined shape such as a disk or rectangle so as to provide the sputtering target. For example, the sputtering target of the embodiment may be a sputtering target for CIGS solar cells.

Modification

The melting step of the embodiment may be replaced by a step for processing finely the diameter of raw material powder particles and then sintering the fine powder material to produce a sintered body.

### EFFECTS OF THE EMBODIMENT

The Cu—Ga alloy of the embodiment is produced such that the Cu—Ga mixture including not less than 40 wt % and not more than 60 wt % of Ga is melted, rapidly cooled to the predetermined temperature, and subjected to thermal treatment. Thereby, the segregation phase (i.e., a phase including 70 wt % or more of Ga) included in the Cu—Ga alloy thus produced can be reduced. Also, the Cu—Ga alloy of the embodiment can be used for making a sputtering target. The sputtering target can prevent a failure to occur in a film formed by sputtering when the segregation phase is melted by heat generated during the sputtering.

The sputtering target produced from the Cu—Ga alloy of the embodiment can prevent voids to occur when sintering a powder so as to provide a densified structure since it is produced, without sintering the powder, through the predetermined cooling step after melting the raw material. Further, the sputtering target of the embodiment can prevent an abnormal electrical discharge to occur in sputtering since it does not contain oxides produced in a sputtering target made by sintering a powder. Thus, by using the sputtering target of the embodiment, a high-quality alloy film can be formed. For example, the alloy film can be used for solar cells to provide the solar cells with excellent conversion efficiency.

Examples 1 to 3 according to the invention will be described below.

### Example 1

In Example 1, a Cu—Ga alloy including 50 wt % Ga is produced by using the production method as mentioned above. A raw material including oxygen-free copper as a matrix and 50 wt % of Ga is melted in a high-frequency melting furnace, the molten raw material is put in a water-cooling mold, and the water-cooling mold is rapidly cooled to 254° C. to produce an ingot with a diameter of 90 mm and a height of 10 mm. Then, the ingot is subjected to thermal treatment at 240° C. for 8 hours in a muffle furnace to produce the Cu—Ga alloy in Example 1. The crystal particles of the Cu—Ga alloy in Example 1 are controlled to be 20 μm in average diameter by adjusting the cooling speed at the cooling step.

### Example 2

Crystal particles of the Cu—Ga alloy finally produced in Example 2 are controlled to be 30 μm in average diameter by adjusting the cooling speed at the cooling step. Except the control in average diameter, in the same manner as Example 1, an ingot in Example 2 is produced, and the ingot is subjected to thermal treatment at 240° C. for 8 hours in a muffle furnace to produce the Cu—Ga alloy in Example 2.

### Example 3

In the same manner as Example 2, an ingot in Example 3 is produced, and the ingot is subjected to thermal treatment at 240° C. for 240 hours in a muffle furnace to produce the Cu—Ga alloy in Example 3.

The middle part of the Cu—Ga alloy ingot in Examples 1 to 3 is cut out for measuring area ratio of the segregation phase. The area ratio of the segregation phase is calculated such that a crystal system in the cutting surface is separated into segregation phase and matrix phase with reference to brightness by using an image analysis software (Image Pro Plus J from Nippon Roper KK). Good results are obtained in Examples 1 to 3 where the area ratio of the segregation phase is 0.7% for the Cu—Ga alloy in Examples 1 and 2, and the area ratio of the segregation phase is 0.5% for the Cu—Ga alloy in Examples 3.

### Comparative Examples

Cu—Ga alloys in Comparative Examples 1 to 7 are produced such that the same raw material as Example 1 is used, the average diameter of crystal particles varies by adjusting the cooling speed at the cooling step, and the thermal treatment conditions varies at the thermal treatment step. The details of the average diameter of crystal particles and the thermal treatment conditions are shown in Table 1. Also, Table 1 shows the area ratio of the segregation phase in the Cu—Ga alloys of Examples 1 to 3 and Comparative Examples 1 to 7.

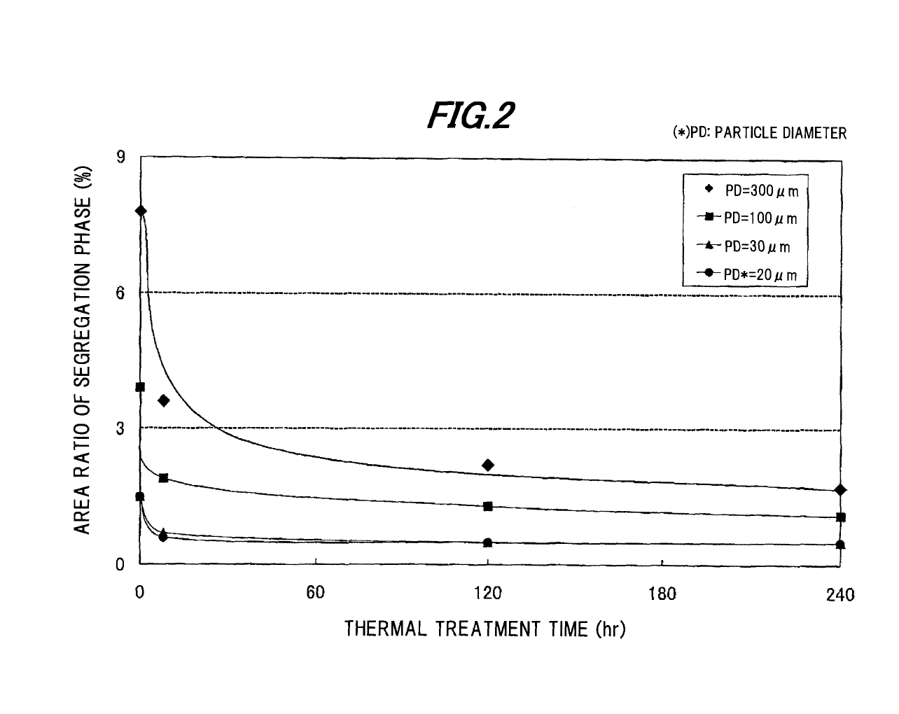

FIG. 2 shows the relationship between the thermal treatment time and the segregation phase area ratio with respect to each average diameter of crystal particles.

TABLE 1

| | | Average | | Area ratio |
|---|---|---|---|---|
| | | diameter (μm) | Thermal | of segre- |
| | Sample | of crystal | treatment | gation |
| Items | No. | particles | conditions | phase (%) |
| Example 1 | 1 | 20 | 240° C. × 8 hrs | 0.7 |
| Example 2 | 2 | 30 | 240° C. × 8 hrs | 0.7 |
| Example 3 | 3 | 30 | 240° C. × 240 hrs | 0.5 |
| Comparative | 4 | 30 | No treatment | 1.5 |
| Example 1 | | | | |
| Comparative | 5 | 100 | No treatment | 4.0 |
| Example 2 | | | | |
| Comparative | 6 | 100 | 240° C. × 8 hrs | 1.7 |
| Example 3 | | | | |
| Comparative | 7 | 100 | 240° C. × 240 hrs | 1.3 |
| Example 4 | | | | |
| Comparative | 8 | 300 | No treatment | 7.8 |
| Example 5 | | | | |
| Comparative | 9 | 300 | 240° C. × 8 hrs | 2.4 |
| Example 6 | | | | |
| Comparative | 10 | 300 | 240° C. × 240 hrs | 1.7 |
| Example 7 | | | | |

Referring to Table 1, the Cu—Ga alloys in Examples 1 to 3 have a good system with a segregation phase area ratio of less than 1% and a fine structure with an average crystal particle diameter of 20 or 30 μm. By contrast, the Cu—Ga alloys in Comparative Examples 1 to 7 are all more than 1% in segregation phase area ratio.

In detail, the Cu—Ga alloys in Comparative Examples 1, 2 are produced without the thermal treatment. It is thereby proved that the area ratio of segregation phase is more than 1% without the thermal treatment. The Cu—Ga alloys in Comparative Examples 3 to 7 are 100 μm or more in average crystal particle diameter. It is thereby proved that when the crystal particles are too big, the area ratio of segregation phase is still more than 1% even with the thermal treatment.

Referring to FIG. 2, it is proved that the area ratio of segregation phase is less than 1% with the thermal treatment more than 8 hours when the average crystal particle diameter is 20 μm (Example 1) or 30 μm (Examples 2, 3).

Although the invention has been described with respect to the specific embodiments and Examples for complete and clear disclosure, the appended claims are not to be thus limited. In particular, it should be noted that all of the combinations of features as described in the embodiment and Examples are not always needed to solve the problem of the invention.

What is claimed is:

1. A Cu—Ga alloy, comprising:
a plurality of phases; and
not less than 40 wt % and not more than 60 wt % of gallium (Ga) and a balance consisting of copper and an inevitable impurity,
wherein the plurality of phases comprise a segregation phase including not less than 80 wt % of gallium (Ga), and
a rate of a volume of the segregation phase to a total volume of the Cu—Ga alloy is not more than 1%.

2. The Cu—Ga alloy according to claim 1, wherein the plurality of phases comprise particles including not less than 40 wt % and not more than 60 wt % of gallium (Ga), the particles comprise a diameter of not less than 0.1 μm and not more than 30 μm, and a rate of a volume of the particles to the total volume of the Cu—Ga alloy is not less than 90%.

3. A Cu—Ga alloy, comprising:
a plurality of phases; and
not less than 40 wt % and not more than 60 wt % of gallium (Ga) and a balance consisting of copper and an inevitable impurity,
wherein the plurality of phases comprise a γ3 phase and an ε phase comprising an alloy of copper and gallium (Ga), and
a rate of a total volume of the γ3 phase and the ε phase to a total volume of the Cu—Ga alloy is not less than 99%.

4. The Cu—Ga alloy according to claim 3, wherein the γ3 phase comprises particles with a diameter of not less than 0.1 μm and not more than 30 μm, and a rate of a volume of the γ3 phase to the total volume of the Cu—Ga alloy is not less than 90%.

5. A sputtering target comprising the Cu—Ga alloy according to claim 1.

6. A method of making a Cu—Ga alloy, comprising:
melting by heating a mixture that comprises not less than 40 wt % and not more than 60 wt % of gallium (Ga) and a balance consisting of copper and an inevitable impurity; and
cooling the molten mixture to 254° C. to solidify particles comprising not less than 40 wt % and not more than 60 wt % of gallium (Ga), and a diameter of not less than 0.1 μm and not more than 30 μm, such that a rate of a volume of the particles to a total volume of the Cu—Ga alloy is not less than 90%.

7. The method according to claim 6, further comprising:
after the cooling, conducting a thermal treatment at a temperature of not less than 200° C. and not more than 254° C. and for not less than 8 hours.

8. The method according to claim 7, wherein the cooling comprises cooling the molten mixture to 254° C. at a cooling speed of 20° C./sec.

9. The method according to claim 8, wherein the melting comprises melting the mixture put in a water-cooling mold or a crucible and the cooling comprises cooling directly the water-cooling mold or the crucible.

10. A method of making a sputtering target, comprising:
forming the Cu—Ga alloy made by the method according to claim 6 into the sputtering target with a predetermined shape.
